(19) United States
(12) Patent Application Publication
(10) Pub. No.: US 2026/0343743 A1
(43) Pub. Date: Oct. 29, 2026

(54) Narrow and Elongated Anti-Pad for High-Speed SerDes Vias

(71) Applicant: Ciena Corporation, Hanover, MD (US)

(72) Inventors: Mukul Tripathi, Varanasi (IN); Rampratap Mahawar, Dausa (IN); Krishan Kant Verma, Gurgaon (IN); Prem Singh, Etah (IN); Ujjwal Tripathi, Faizabad (IN)

(73) Assignee: Ciena Corporation, Hanover, MD (US)

(21) Appl. No.: 19/232,179

(22) Filed: Jun. 9, 2025

(30) Foreign Application Priority Data
Apr. 24, 2025 (IN) 202541039530

(51) Int. Cl. H05K 1/11; H05K 1/02

(52) U.S. Cl. CPC H05K 1/116; H05K 1/0216; H05K 2201/09609; H05K 2201/09618; H05K 2201/09636; H05K 2201/09854

(57) ABSTRACT

A printed circuit board (PCB) structure for routing high-speed differential SerDes signals is provided. The structure can include a plurality of vias arranged to define a differential pair defining a via pitch and a via center, a differential anti-pad surrounding each via of the plurality of vias of the differential pair, each anti-pad includes a geometry defining a length, a width, a semicircular end and a displacement distance between the semicircular end and the via center.

### FIELD OF THE DISCLOSURE

The present disclosure relates generally to computing and printed circuit board design. More particularly, the present disclosure relates to devices and methods for narrow and elongated anti-pad design for high speed SerDes vias.

### BACKGROUND OF THE DISCLOSURE

The design of high-speed printed circuit boards (PCBs) for connectors and application-specific integrated circuits (ASICs) presents a number of layout challenges, particularly when routing differential serializer/deserializer (SerDes) signals, single-ended signals, and power planes. As ASICs and connectors continue to evolve, they increasingly feature non-uniform pin footprints, such as zig-zag or matrix arrangements, and tighter pin pitches, often below 1 mm. These irregular patterns complicate the placement and routing of vias, especially in dense fan-out regions where maintaining signal integrity is essential. Differential SerDes traces, in particular, require tightly controlled impedance matching, often targeting 93Ω, 95Ω, or 100Ω, making the physical design of vias and their corresponding anti-pads critical to overall performance.

Conventional techniques for addressing these challenges typically focus on reducing via capacitance by modifying anti-pad geometries, often using oval, elliptical, or otherwise asymmetrical shapes, to move the ground cutouts away from sensitive signal paths. While these approaches can help improve impedance matching and minimize disruption to power and reference planes, they are not universally effective. In practice, existing solutions often fail to account for the increasingly complex geometries and tighter constraints of modern ASICs, leading to suboptimal signal integrity, power plane stitching, or excessive routing detours. As such, there remains a need for improved signal transition structures that address these evolving design constraints while ensuring electrical performance and layout flexibility.

### BRIEF SUMMARY OF THE DISCLOSURE

The present disclosure relates to the anti-pad structures configured to reduce crosstalk. More specifically, the present disclosure provides a narrow and elongated anti-pad geometry for differential SerDes pair vias. Notably, the narrow and elongated geometry of the anti-pad can be effective for increasing the performance of the vias, for example by reducing crosstalk. In some aspects, the cross-section of the anti-pad can include semicircular extreme ends which can be centered outside the corresponding via center. Again, the semicircular ends of the anti-pad can be off-center compared to the vias and displaced therefrom and define a distance between the vias and the semicircular end. When compared to conventional anti-pad shapes, which are always centered at their corresponding via center with only a varying radius, the shape of the via of the present disclosure is substantially elongated and narrow.

In one aspect, disclosed is a signal transition structure comprising a via extending through a printed circuit board (PCB) substrate, the via defining a via pitch and a via center, and an anti-pad disposed about the via, the anti-pad comprising an elongated geometry defining a length, a width narrower than the length, and at least one semicircular end, wherein a center of the semicircular end is offset from the via center by a displacement distance greater than zero, the elongated geometry is configured such that the length is a sum of the via pitch and two times the sum of a radius of the semicircular end and the displacement distance.

In another aspect, disclosed is a printed circuit board (PCB) structure for routing high-speed differential SerDes signals, comprising a plurality of vias arranged to define a differential pair defining a via pitch and a via center, a differential anti-pad surrounding each via of the plurality of vias of the differential pair, each anti-pad comprising, a geometry defining a length, a width, a semicircular end and a displacement distance between the semicircular end and the via center.

### BRIEF DESCRIPTION OF THE DRAWINGS

The present disclosure is detailed through various drawings, where like components or steps are indicated by identical reference numbers for clarity and consistency.

FIG. 1 is a schematic view of an exemplary embodiment of a power plane being stitched by differential anti-pads to allow less current flow.

FIG. 2 is a cross-sectional view of a pair of standard anti-pads.

FIG. 3 is a cross-sectional view of a narrow anti-pad in accordance with one aspect of the present disclosure.

FIG. 4 is a graphical view of simulations comparing the geometries of the standard anti-pads of FIG. 3 to the narrow anti-pad of FIG. 4.

FIG. 5 is a schematic view depicting a comparison of a trace fanout of the standard anti-pad of FIG. 3 and a trace fanout of an narrow anti-pad of FIG. 4 in accordance with another aspect of the present disclosure.

FIG. 6 is a schematic view depicting a comparison between an anti-pad diving board of the standard anti-pad of FIG. 3 and an anti-pad diving board of a narrow anti-pad of FIG. 4 in accordance with another aspect of the present disclosure.

FIG. 7 is a graphical view providing GND reference of SerDes and a power shape comparison and of the standard anti-pad of FIG. 3 to the narrow anti-pad of FIG. 4.

FIG. 8 is an alternative schematic view comparing the geometries of the standard anti-pad of FIG. 3 to the narrow anti-pad of FIG. 4.

### DETAILED DESCRIPTION OF THE DISCLOSURE

Again, the present disclosure generally relates to via anti-pad and line geometries to reduce excess capacitance or introduce inductance. More specifically, one aspect of the present disclosure provides a narrow and/or elongated anti-pad for differential SerDes. Narrow and elongated can generally mean that the length of the anti-pad is longer than the width. Moreover, narrow and elongated can be used interchangeably. More specifically, the anti-pad can define semicircular extreme ends which are centered outside of the corresponding via centers. In contrast, in standard anti-pads the ends are always centered at their via centers and only the radius is varied. Again, in some aspects, the anti-pad of the present disclosure does not share common centers which results in a substantially elongated and narrow anti-pad.

### Conventional Anti-Pad

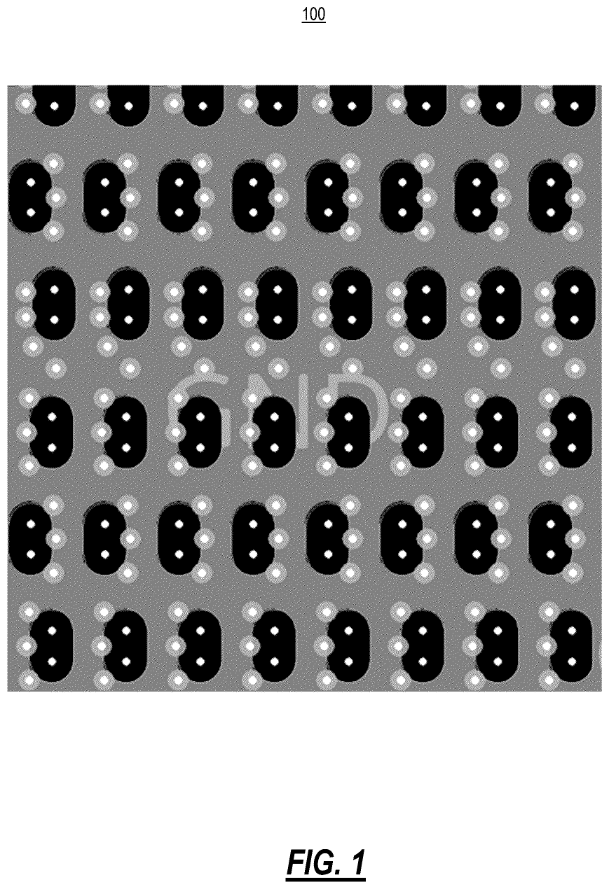

Turning now to FIG. 1, a schematic view of a power plane 100 is shown and described. When designing routing layouts for high-speed connectors or Application-Specific Integrated Circuits (ASICs), it's important to consider a range of electrical and physical factors that can impact signal integrity and overall system performance. An ASIC is a custom-designed chip tailored to perform a specific function or set of functions, often within a larger electronic system. These chips and the Printed Circuit Boards (PCBs) that house them frequently incorporate differential SerDes (Serializer/Deserializer) traces. A SerDes is a key component in high-speed communication systems, responsible for converting data between serial and parallel formats to enable faster data transmission over fewer physical connections. These high-speed differential signals often coexist and interact with single-ended signals and power planes on the same PCB, creating potential for signal interference, crosstalk, and impedance mismatches if not carefully managed. Proper routing techniques, impedance control, and isolation strategies are therefore essential to ensure reliable performance in these complex, high-speed environments.

Different ASICs and high-speed connectors come in a wide variety of formats, each with its own layout and electrical implications. For instance, connector arrangements may follow zig-zag or matrix patterns and can vary in pin pitch, commonly ranging from 1.0 mm to 0.8 mm or even smaller. These physical differences introduce significant challenges when placing differential vias for SerDes signals, which require tightly controlled impedance to maintain high-speed signal integrity. One aspect of via design is the use of anti-pads, which can be clearance areas around vias in power or ground planes intended to reduce parasitic capacitance. Improperly designed anti-pads can unintentionally stitch power or ground planes, or worse, sever reference planes relied upon by neighboring SerDes traces. This can result in degraded signal quality, increased noise coupling, and potential system-level interference. FIG. 1 illustrates such an example scenario, where SerDes ground reference planes (GND) are interrupted by the anti-pads of adjacent signal vias, effectively stitching or cutting through the shared power/GND planes. These design pitfalls underscore the importance of holistic PCB planning, where via placement, anti-pad geometry, and layer stack-up are all optimized to preserve clean signal paths and robust isolation for high-speed communication.

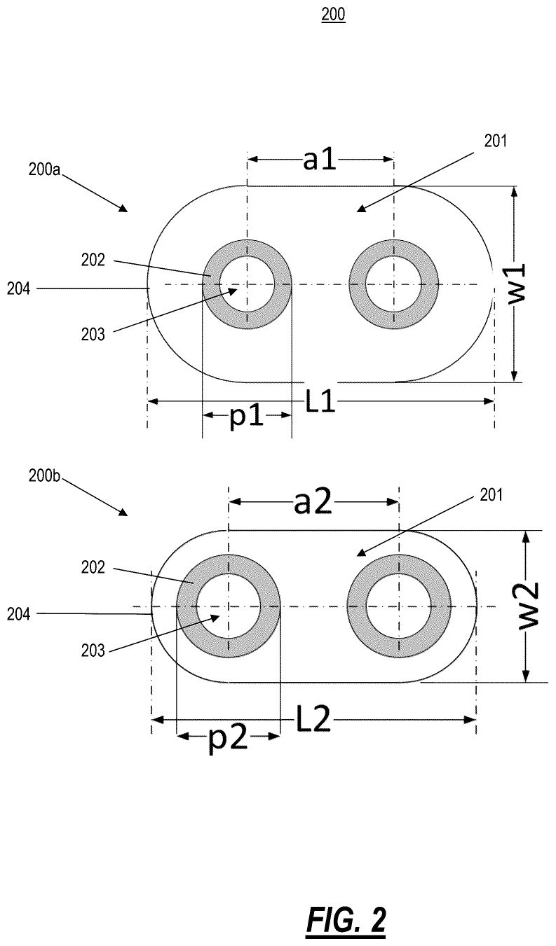

Turning now to FIG. 2, a cross-section of a pair of standard anti-pads 200 is shown and described. In such example, the standard anti-pad 200 can be a bigger standard anti-pad 200a and a smaller standard anti-pad 200b. In some aspects, the standard anti-pads 200 can be disposed around at least one via 202. For example, the standard anti-pad 200 can be disposed around two vias 202. The via 202 can define a via center 203, which can be a geometric center of the via 202. The standard anti-pads 200 can define a width w1, w2, and a length 11, 12. The via 202 can define a via pitch a1, a2 and a via size p1, p2. In some aspects, the via 202 can be a small hole in a PCB which can be in electrical communication between different layers of the board. Often, the via 202 can be filled or plated with a conductive material (e.g., copper or silver) which can be configured to promote the flow of electricity. Often, vias 202 can be utilized in multilayer PCBs where components and traces span multiple levels. The anti-pad area 201 can be a non-conductive area around the via 202. More generally, the anti-pads can be an area in a PCB. The anti-pads can be configured to separate electrical communication between the layers of the PCB. In some embodiments, anti-pads can be a gap or a void in a layer, such as a cooper layer. Again, anti-pads can be any structure or void configured to maintain electromagnetic isolation and optionally prevent short circuits for example by controlling impedance.

In some aspects, standard anti-pad 200 can include a semicircular end 204. It should be noted that standard anti-pads 200 do not have a varying length 11, 12 and likewise only vary the width w1, w2. In other words, the semicircular end 204 and the vias 202 share a common center. In some cases, for standard anti-pads 200, only a radius of the via 202 varies. More generally, in standard anti-pads 200, the semicircular end 204 and the via 202 share a common center at a via center 203 and there is no variation in the length 11, 12.

In more detail, standard anti-pads 200 are typically designed with a symmetric geometry centered around the via 202, where the semicircular end 204 shares the same center point as referred to as the via center 203. This symmetrical configuration simplifies the manufacturing process and helps ensure consistent electrical characteristics. However, because the length dimensions 11, 12 remain constant, standard anti-pads 200 are limited in their ability to adapt to directional variations in signal flow or nearby impedance-sensitive structures. Only the radius of the via 200 or the width w1, w2 of the anti-pad may be modified, which restricts how precisely the impedance and return current path can be tuned for high-speed signals, especially differential pairs. This uniformity can also lead to unnecessary plane disruption in one direction even when only minimal clearance is needed, potentially cutting into adjacent reference planes and causing electromagnetic interference (EMI) or increased signal loss. As PCB designs become more compact and signal speeds increase, these constraints highlight the need for more advanced or adaptive anti-pad geometries that allow asymmetrical shaping or directional clearance to optimize signal performance while minimizing collateral interference.

### Narrow Anti-Pad

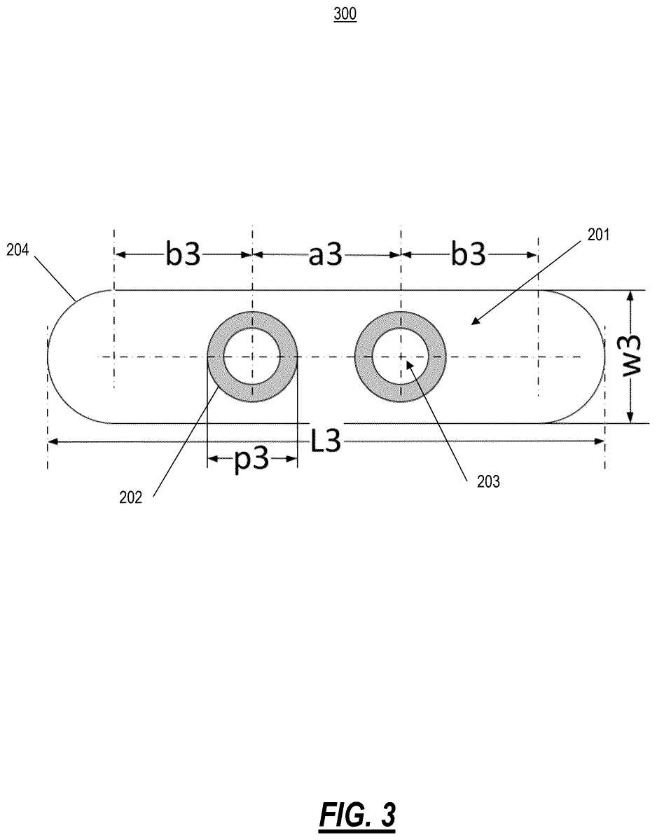

Turning now to FIG. 3, a cross-section of a narrow anti-pad 300 is shown and described. When optimizing flip-chip transitions and bump patterns, particularly for high-speed ASICs, key factors must be carefully balanced, such as line impedance, available routing space, and the intrinsic pad capacitance within the flip-chip die. Achieving target impedance values (e.g., 50Ω or 85Ω) is rarely straightforward, especially when working within the strict design constraints of modern host materials such as PCBs, SLPs (Substrate-Like PCBs), or HDI/HDUB substrates. These platforms often impose dense bump patterns and tight design rules, leaving minimal flexibility for straightforward or idealized signal transitions. As a result, Time Domain Reflectometry (TDR) often reveals significant deviations from the desired characteristic impedance (Zo) and return loss (RL) metrics can be adversely affected. In practice, designing for higher impedance values becomes increasingly difficult due to two compounding factors: the inherently high pad capacitance associated with the ASIC die and the limited inductance that can be realized within the physical confines of the bump geometries. The present disclosure provides an anti-pad configuration to mitigate these effects and tune the signal transition for optimal performance by adjusting via anti-pad shapes to reduce capacitive coupling, and modifying trace widths, stubs, or clearances to introduce compensatory inductance. These tuning techniques become critical to achieving signal integrity targets, particularly in ultra-dense, high-speed interconnect designs where even minor mismatches can lead to performance degradation. One such embodiment provided herein is the narrow anti-pad 300.

The narrow anti-pad 300 can be disposed around the via 202. In some aspects, the narrow anti-pad 300 can surround a plurality of vias 202. For example, the narrow anti-pad 300 can surround a pair of vias 202. The via 202 of the narrow anti-pads 300 can define the via center 203, a via pitch a3, and a via size p3. The narrow anti-pad 300 can define a length 13 and a width w3. The narrow anti-pad 300 can include the semicircular end 204. In some aspects, the narrow anti-pad 300 can include a pair of opposed semicircular ends 204. Importantly, in many aspects, the semicircular end 204 of the narrow anti-pad 300 is distal to the via 202. More specifically, the semicircular end 204 of the narrow anti-pad 300 is displaced from the via 202 by a displacement b3. In other words, the semicircular end 204 is not coaxial with the via 202 and is separated therefrom via the displacement b3. Again, the narrow anti-pad 300 in accordance with the present disclosure is configured such that the semicircular ends 204 are centered outside the via centers 203. When compared to the standard anti-pad 200, the narrow anti-pad 300 of the present disclosure is substantially narrow and elongated, having a length 13 which is much greater than the width w3.

The narrow anti-pad 300 is a departure from the standard anti-pad 200 at least by introducing an elongated geometry. The elongated and ovular cross-section of the narrow anti-pad 300 can modify the electromagnetic environment surrounding the vias 202. Unlike the standard anti-pad 200, where the semicircular ends 204 are typically concentric with the via center 203, the semicircular ends 204 of the narrow anti-pad 300 are displaced by the distance b3 from the via center 203. This displacement b3 can be asymmetric or symmetric, which can be adapted to modify the return current paths and can influence the effective capacitance and inductance around the vias 202. In some aspects, the narrow anti-pad 300 can be applied to differential pairs, such as pairs of vias 202. In such embodiments, the narrow anti-pad 300 can be shaped to substantially surround two adjacent vias 202 while maintaining a tight via pitch a3 and a controlled via size p3. In this configuration, the narrow anti-pad 300 is characterized by a greater longitudinal extent or length 13 compared to its transverse dimension or width w3, giving it a slender, capsule-like appearance, It is envisioned that the narrow anti-pad 300 can adopt a profile substantially similar to, without limitation to a capsule, a stadium or racetrack shape, an ellipse, a superellipse (or Lame Curve), a rounded rectangle, an oblong, a double semi-circle, or the like. This elongation can permit more precise control over the distribution of copper voids in the power or ground plane, enabling the reduction of unwanted parasitic capacitance and better manage signal integrity for high-speed differential signals such as SerDes lines. Furthermore, by placing the semicircular ends 204 away from the via center 203, the narrow anti-pad 300 can help isolate the electromagnetic interaction between the signal vias 202 and nearby stitching or reference planes 100, minimizing interference and crosstalk. More generally, the narrow anti-pad 300 geometry can offer a tuned approach to balancing impedance control, crosstalk suppression, and return path integrity in dense, high-performance PCB designs. The following table provides a comparison of the geometries between the standard anti-pads 200, 200a, 200b and the narrow anti-pad 300.

| Anti-Pad | Dimensions | Description |
|---|---|---|
| Bigger Standard Anti-Pad | Via pitch => a1 = a2 = a3 | A bigger Antipad with |
| 200a | Via Size => p1 = p2 = p3 | semicircular ends centered |
| | Anti-pad Width => w1 > | at via centers. |
| | (w2 = w3) => Wider than | |
| | w2 | |
| | Anti-pad Length => L1 = | |
| | a1 + w1 > L2 | |
| | b1 = b2 = 0; as both semi- | |
| | circle ends are centered at | |
| | via centers. | |
| Smaller Standard Anti-Pad | Via pitch => a1 = a2 = a3 | A Smaller Antipad with |
| 200b | Via Size => p1 = p2 = p3 | semicircular ends centered |
| | Anti-pad Width => w1 > | at via centers. |
| | (w2 = w3) => narrower | |
| | than w1 | |
| | Anti-pad Length => L2 = | |
| | a2 + w2 < L1 => shorter | |
| | b1 = b2 = 0; as both semi- | |
| | circle ends are centered | |
| | at via centers. | |
| Narrow Anti-pad 300 | Via pitch => a1 = a2 = a3 | An elongated and narrow |
| | Via Size => p1 = p2 = p3 | Antipad with semicircular |
| | Anti-pad Width => w1 > | ends centered outside the |
| | (w2 = w3) => narrower | via centers. |
| | Anti-pad Length => L3 = | |
| | a3 + w3 + b3 | |
| | b3 > 0; as both semi-circle | |
| | ends are not centered at via | |
| | center whereas centered | |
| | outside so total length of | |
| | anti-pad increased with | |
| | narrow width. | |

For the bigger standard anti-pad 200a, the via pitch and size are consistent (a1=a2=a3, p1=p2=p3), but it features a wider anti-pad (w1>w2=w3) and a longer length (L1=a1+w1>L2). Here, both semicircular ends 204 are centered on the vias 202 at the via center 203, so b1=b2=0. The smaller standard anti-pad 200b maintains the same via pitch and size but uses a narrower anti-pad (w1>w2=w3) and shorter length (L2=a2+w2<L1), also with b1=b2=0 due to centered semi-circles. In contrast, the narrow anti-pad 300 of the present disclosure retains the same pitch and via size but introduces a narrower width (w1>w2=w3) and an extended length (L3=a3+w3+b3) because its semicircular ends 204 are not centered on the via 202, but are offset (b3>0) by the displacement, effectively increasing the narrow anti-pad's 300 length while maintaining a compact width. Again, the narrow anti-pad 300 of the present disclosure is much narrower and more elongated than the standard anti-pad 200.

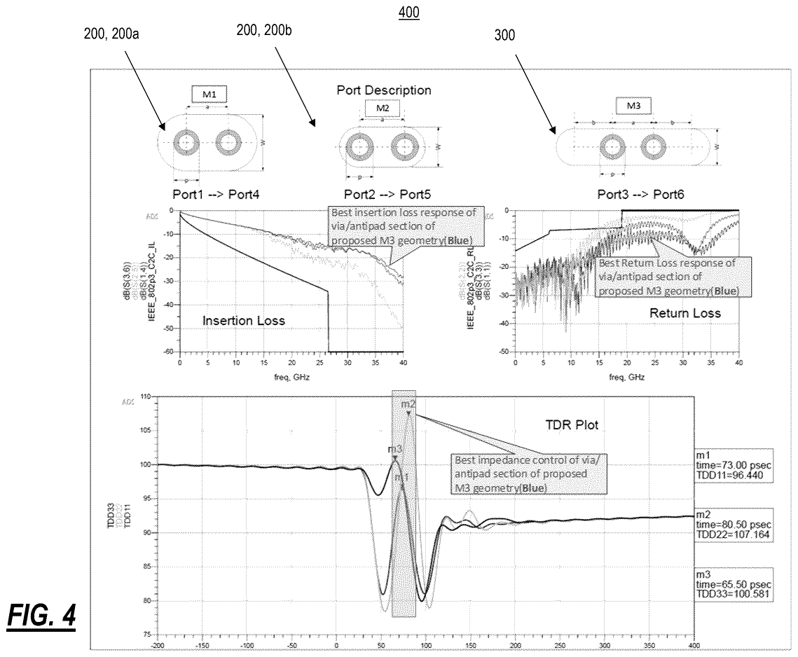

Turning now to FIG. 4, the results 400 from an exemplary simulation comparing the standard anti-pad 200 and the narrow anti-pad 300 are shown and described. Note, the following results are intended for illustrative purposes only. The analysis of standard anti-pad 200 and narrow anti-pad 300 geometries shows that the narrow anti-pad 300 geometry provides the most optimal electrical performance for high-speed differential SerDes traces. Firstly, TDR results show that the narrow anti-pad 300 maintains a tightly controlled differential impedance of 100.58Ω, which is exceptionally close to the target 100Ω standard for SerDes transmission lines. In contrast, the standard anti-pad 200 geometries exhibit greater impedance deviations, measuring 96.44Ω and 107.164Ω respectively, which can lead to signal reflections, degraded signal integrity, and timing issues in high-speed applications.

Secondly, when analyzing insertion loss, which measures how much signal power is lost as it passes through the via structure, the narrow anti-pad 300 again outperforms the other two geometries. As shown in the exemplary results of FIG. 4, the narrow anti-pad 300 exhibits minimal insertion loss up to 40 GHz, meaning it allows maximum signal transmission with the least amount of power loss, which can be important for maintaining data integrity over high frequencies. Finally, the return loss, which quantifies the amount of signal reflected back toward the source, also favors the narrow anti-pad 300. More specifically, the narrow anti-pad 300 of the present disclosure demonstrates the lowest return loss up to 40 GHz, indicating superior impedance matching and minimal signal reflection. This performance directly contributes to cleaner signal transmission, reduced jitter, and better eye diagram quality. Overall, the results from the exemplary simulation support that the narrow anti-pad 300 geometry is clearly the most effective among the three, providing the best balance of controlled impedance, lowest insertion loss, and optimal loss performance in high-frequency SerDes applications.

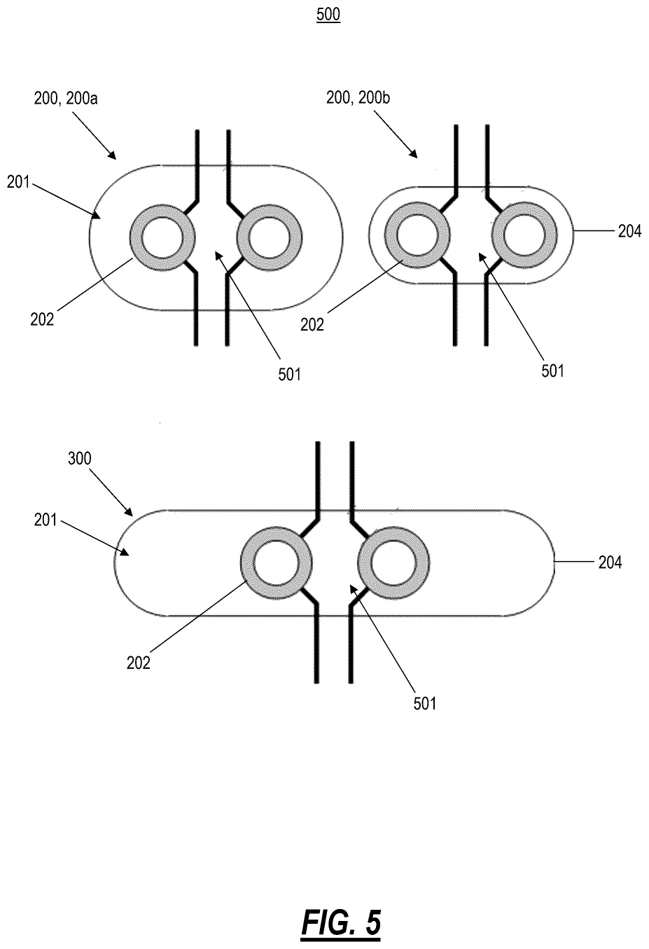

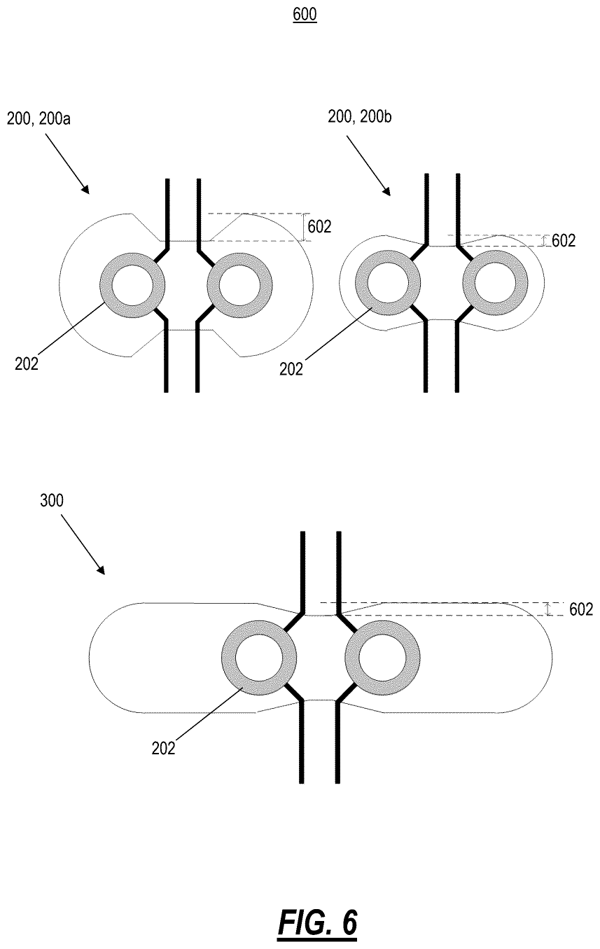

Turning now to FIG. 5, an anti-pad trace fanout comparison 500 of the standard anti-pad 200, 200a, 200b and the narrow anti-pad 300 is shown and described. Additionally, FIG. 6 depicts an anti-pad diving board comparison 600 of the standard anti-pad 200, 200a, 200b and the narrow anti-pad 300 is shown and described. The standard anti-pad 200 of FIG. 5 depicts a length of trace 501. Similarly, the narrow anti-pad 300 of the present disclosure as shown in FIG. 5 depicts the length of trace 501. In some aspects, the length of trace 501 can be a length of a PCB trace (i.e., the conductive copper path between components). In other aspects, the length of trace 501 can be a dimension defining a shape of an anti-pad around a via, for example when it is used for differential pair routing, such as in SerDes signal routing. Again, an anti-pad can refer to a clearance hole in a reference plane (such as a ground or power plane) surrounding a via. Anti-pad holes can be structured to prevent unwanted coupling or shorting between the via and the plane. In some aspects, anti-pad length can be the distance from one end of the anti-pad to the other, measured along the direction of signal flow or parallel to the trace. In some aspects, the anti-pad width can be a clearance width which is perpendicular to the trace. Again, the length of trace 501 in the anti-pad region can refer to how much of the signal path (trace) is affected by passing through the anti-pad clearance area. For example, and without limitation, in high speed design, this length can be relevant because the trace can experience a discontinuity in impedance due to a missing reference plane in the anti-pad area.

The bigger standard anti-pad 200a has more length of trace 501 without GND reference. The smaller standard anti-pad 200b has less length of trace 501 without GND reference. In some aspects, the narrow anti-pad 300 has less trace length without GND reference. Notably, the longer length of trace 501 of the standard anti-pad usually means greater impedance discontinuity, more return current disturbance, higher insertion and return losses, and reflection or degraded signal integrity. On the other hand, short trace lengths like that of the narrow anti-pad 300 of the present disclosure can minimize these effects, for example by maintaining a tighter impedance profile which can ensure better signal transmission, especially at higher frequencies.

The narrow anti-pad 300 geometry features the smallest fanout length of trace 501 from differential vias that lacks a direct reference plane, as illustrated in FIG. 5. This minimal trace segment without reference is useful in high-speed SerDes routing because it reduces the distance over which the signal experiences impedance discontinuity due to the absence of a nearby return path. In typical via structures, when the trace 501 exits the via 202 and passes through the anti-pad region, it loses its reference to the ground or power plane, which can cause signal distortion, increased insertion loss, and reflections. However, by optimizing the narrow anti-pad 300 to minimize this unreferenced trace length, the signal integrity (SI) performance is significantly enhanced. As a result, the narrow anti-pad 300 geometry as first shown in the present disclosure enables smoother signal transitions from via to trace, maintaining a closer impedance match and reducing high-frequency losses.

FIG. 6 depicts the standard anti-pads 200 compared 600 to the narrow anti-pads 300. More specifically a diving board 602 of the standard anti-pads 200 and the narrow anti-pads 300 is shown. The diving board 602 can refer to a section of the differential trace that extends beyond a reference plane in the anti-pad region before connecting to the via 202. When routing differential pairs (like SerDes signals), each signal in the pair connects to the via 202 that transitions the trace 501 from one layer to another. Around each via 202, a clearance hole (anti-pad) is created in the ground or power plane to prevent electrical shorts. If the trace 501 extends into this anti-pad region without a ground or power plane underneath it, that segment becomes unsupported by a reference plane. This “unsupported” trace acts like a cantilever beam, and because it “sticks out” over the anti-pad region without return path continuity, it resembles a diving board (hence the nickname). The diving board 602 region are provided for matching impedance. Minimizing the length and width of the diving board 602 helps in design complexity, leading to better performance in differential SerDes routing.

Notably, the bigger standard anti-pad 200a has a greater diving board 602. In contrast, the narrow anti-pad 300 of the present disclosure has a smaller diving board. To compensate for the unreferenced fanout segment shown in FIG. 5, traditional designs often require the use of larger diving boards 602 on adjacent ground (GND) reference layers. These diving boards 602, or extensions of the ground plane underneath the trace 501 are intended to partially restore the return path that is lost in the anti-pad region, helping to maintain impedance continuity and reduce signal integrity degradation. However, such compensations can increase PCB layer complexity and take up valuable routing space. In contrast, the narrow anti-pad 300 of the present disclosure geometry significantly minimizes or even eliminates the need for such diving boards, as shown in FIG. 6. By reducing the length of trace 501 that is unsupported by a reference plane, narrow anti-pad 300 of the present disclosure ensures that the return path remains more continuous and tightly coupled to the differential trace. This leads to better impedance control, less high-frequency loss, and overall improved SerDes performance, all without relying on additional ground structures that complicate fanout and layout design.

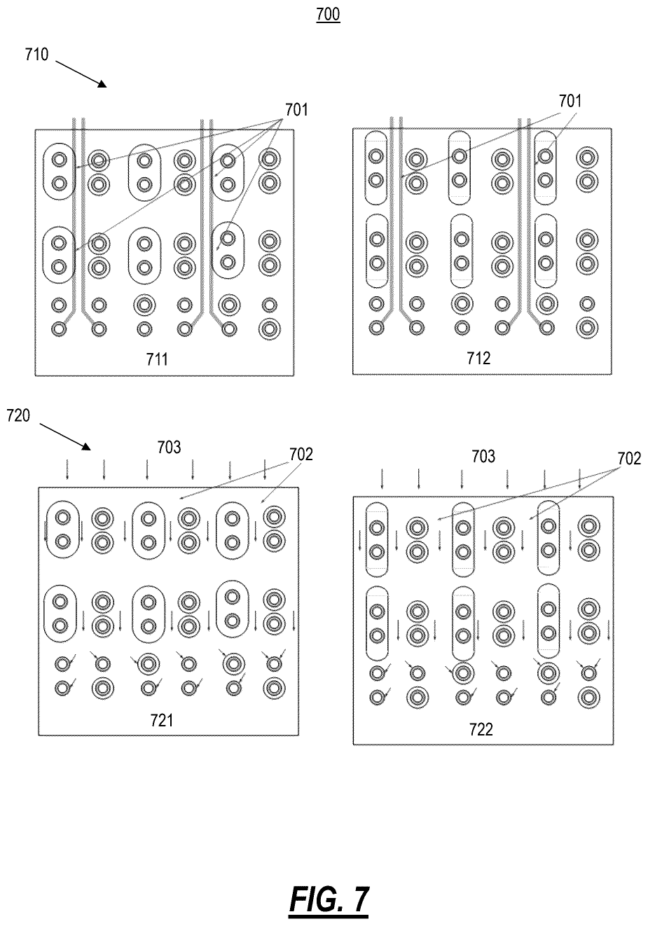

Turning now to FIG. 7, a graphical comparison 700 between the power planes 710 and power shapes 720 of the standard anti-pads 200 and the narrow anti-pads 300 of the present disclosure. More specifically, FIG. 7 provides a comparison of the standard anti-pad power layers 711 and the narrow anti-pad power layers 712 of the present disclosure, and the standard anti-pad power shape 721 and the narrow anti-pad power layers 722 of the present disclosure. The power layer 710 comparison depicts a reference cut 701. The power shape 720 comparison depicts a power plane 702 and a current flow 703.

The narrow anti-pads 300 geometries of the present disclosure are less likely to cause ground (GND) reference plane cutting issues compared to the standard anti-pad 200 geometry shown. This is primarily due to the narrower width w3 used in the narrow anti-pad 300. In high-speed PCB layouts, especially for SerDes differential signals, it's critical to preserve continuous GND reference planes to maintain signal integrity and consistent return paths. Wider anti-pads, such as those standard anti-pad 200 geometries, increase the risk of cutting across or segmenting the GND plane, which disrupts the return current flow and introduces impedance discontinuities. By minimizing the anti-pad width, the narrow anti-pads 300 reduce the area removed from the reference layer, preserving the integrity of the ground plane and thus ensuring better electrical performance, particularly at high frequencies. This makes the narrow anti-pad 300 provided by the present disclosure more robust options in complex fanout compared to standard anti-pads 200 regions where preserving the reference is crucial.

The narrow anti-pads 300 geometries of the present disclosure offer a significant layout advantage over the standard anti-pad 200 geometry due to their narrower anti-pad widths, which result in more available space for power planes within the power layers 710 of the PCB, especially between adjacent anti-pads. In dense ASIC or connector footprints where power delivery and high-speed signal integrity must coexist, optimizing space for uninterrupted power planes 710 is crucial. The wider anti-pad design in the standard anti-pad 200 geometries consume more area, reducing the continuity and effectiveness of power distribution. In contrast, the narrow anti-pads 300 geometries of the present disclosure free up valuable space, allowing for more robust and less obstructed power routing. However, for the narrow anti-pads 300 geometries of the present disclosure to fully realize this benefit, its orientation can be aligned with the direction of current flow 703 from the power source to the power load pins. This can ensure minimal disruption to the current flow 703 and optimal power integrity. This alignment helps maintain low impedance in the power delivery network while still supporting high-speed signal requirements.

The narrow anti-pad 300 geometry provided herein is particularly well-suited for BGA (Ball Grid Array) packages of ASICs and connectors with small pitch sizes, where routing space is extremely limited. As newer and more advanced components continue to shrink in size, their pin pitches become tighter, often reaching 0.8 mm or less, which significantly constrains fanout routing and via 202 placement. In such scenarios, the narrow and compact design of the narrow anti-pad 300 provided herein becomes a key advantage. It allows differential vias 202 and associated traces 501 to be placed more efficiently without violating design rules or compromising impedance control. Additionally, the narrow anti-pad 300 geometry minimizes interference with surrounding power and ground planes, helping to preserve signal integrity and power delivery in dense layouts. As a result, the narrow anti-pad 300 geometry can provide an optimal balance of electrical performance and mechanical layout feasibility for modern high-density ASIC and connector applications.

### Narrow Anti-Pad Geometry

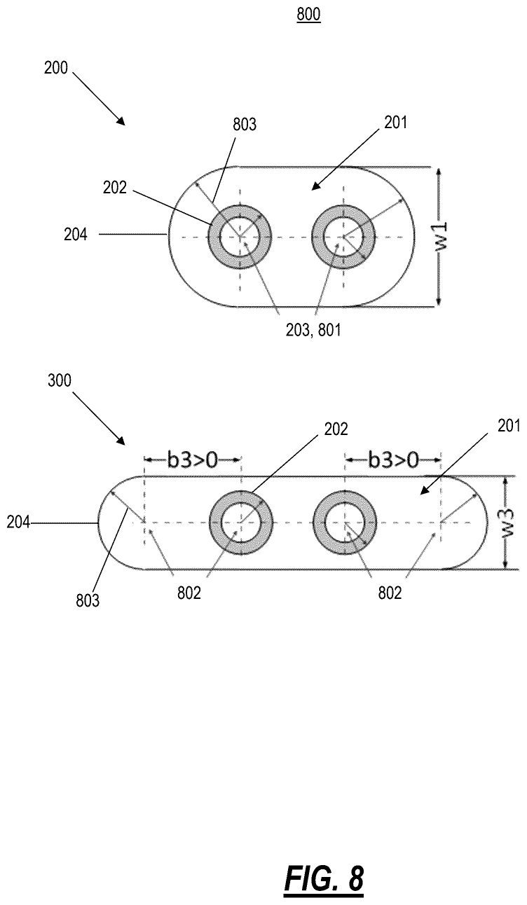

Turning now to FIG. 8, a dimensional comparison 800 between the standard anti-pad 200 vias and the narrow anti-pad 300 vias is shown and described. Notably, the narrow anti-pad 300 configuration is disclosed in the present disclosure only. The term “narrow” generally refers to an elongated shape, with a length greater than the width. In some embodiments, the length can be a multiple of the width. The narrow anti-pad 300 can define the displacement b3. The displacement b3 of the narrow anti-pad 300 is greater than 0. Notably, there is no displacement on the standard anti-pad 200. In all standard anti-pad 200 geometries, the semicircular end 204 and the via center 203 share a common center 801. This common center 801 can be substantially coaxial and can be common on any of the x-axis, y-axis, or z-axis. However, the narrow anti-pads 300 can define a non-centered 802 arrangement. More specifically, the center of the semicircular end 204 and the via 202 of the narrow anti-pad 300 are not centered.

More generally, the present disclosure provides the narrow anti-pad 300 for a differential SerDes. Standard anti-pads 200 are designed with semicircular ends 204 that are centered directly over the corresponding via centers 203, resulting in a fixed geometry where the anti-pad length 11, 12 is determined solely by a radius 803 of the semicircular end 204. In such cases, the displacement parameter ‘b’, which can be the offset distance from the via center 203 to the center of the semicircular end 204, is always zero (b=0), and only the width ‘w’ of the anti-pad is adjusted to meet impedance requirements. In contrast, the narrow anti-pad 300 is elongated and can depart from this conventional structure by shifting the centers of the semicircular ends away from the via centers 203, effectively making the displacement ‘b’ greater than zero (b>0). This shift elongates the anti-pad without increasing its width w3, maintaining a narrow profile while increasing the overall length 13. This geometry provides better control over impedance and signal integrity, especially in high-speed differential SerDes routing, where space is constrained, and precise electromagnetic behavior is crucial. The elongated form also offers more design flexibility and minimizes disruption to nearby power and reference planes, making it particularly advantageous in modern dense PCB layouts.

In an example embodiment only without limitation, the length of the standard anti-pad 200 can be calculated as follows:

l=a+2r

In the foregoing example, the length can be the sum of the length of the via pitch and two times the radius of the semicircular end radius 803, represented as r. In contrast, the following exemplary equation provides the length of the narrow anti-pad 300 of the present disclosure:

l₃=a+2(r+b)>w

As shown above, the length of the narrow anti-pad is the sum of the via pitch and two times the sum of the semicircular radius 803 and the displacement b. Accordingly, the length of the narrow anti-pad is greater than the width. In addition, the length of the narrow anti-pad 300 can be tuned by manipulating any of the via pitch, the radius, or the displacement distance. In some aspects, each of the variables are substantially equivalent. In other aspects, each of the variables are non-equivalent.

The narrow anti-pad 300 geometry can be used in differential SerDes pair vias in high-speed PCB systems. Unlike the standard anti-pad 200 geometries, where the semicircular ends 204 of the anti-pad 201 are centered directly on the via centers 203 (i.e., with offset b=0), the narrow anti-pad 300 design can include semicircular ends 204 that are centered outside the via centers 802, creating a narrow and elongated anti-pad with b>0. Moreover, the narrow anti-pad 300 can be configured to allow an increase in the total length 13 of the anti-pad 201 while keeping the width w3 narrow with respect to the length 13, which can significantly improve signal integrity and electromagnetic performance, especially in dense BGA areas.

From a signal performance perspective, in an exemplary embodiment only without limitation, the narrow anti-pad 300 demonstrates superior TDR response, achieving a controlled impedance of 100.58Ω, which is close to the target 100Ω differential impedance required for SerDes traces. In comparison, the standard anti-pad 200 geometries deviate more significantly, showing impedance values of 96.44Ω and 107.16Ω, respectively. These deviations can lead to signal reflections, timing issues, and degradation in high-speed channels. As such, in the foregoing example, the narrow anti-pad 300 design's impedance consistency highlights its optimized structure for high-speed applications.

Additionally, continuing with the example, the insertion loss and return loss responses for the narrow anti-pad 300 geometry can also be notably better than the conventional alternatives. Simulation data up to 40 GHz shows that M3 has the least amount of insertion and return losses, indicating lower energy dissipation and reflection at high frequencies. This makes the narrow anti-pad 300 design highly suitable for next-generation SerDes applications operating at 112 Gbps or higher. In further continuation with the example, the fanout structure also benefits from the narrow anti-pad 300 geometry. The smallest fanout trace from differential vias can be routed without needing a reference plane cut, improving signal integrity during via transitions. Traditional geometries often require compensation via large diving boards on adjacent GND reference layers to maintain continuity, which consumes valuable board space and complicates stack-up design. In contrast, the narrow anti-pad 300 requires minimal or no diving board compensation, further reducing layout complexity and conserving layer real estate.

In accordance with another aspect of the present disclosure, in terms of PCB stack-up efficiency, the narrow anti-pad 300 geometry, due to its narrower width compared to the standard anti-pad 200, can minimize the risk of ground reference cuts, which are common issues in denser layouts. This not only ensures better return path continuity but also provides more space between adjacent anti-pads, allowing improved routing of power planes in the inner power layers of the PCB. In one example, for optimal performance, the narrow anti-pad 300 can be aligned in the direction of current flow 703 from the power source to the load pins, ensuring minimal disruption to power distribution. Lastly, in yet another non-limiting example, the narrow anti-pad 300 geometry is particularly well-suited for BGA packages of ASICs and connectors with tight pin pitches, where space is at a premium, and performance margins are tight. Its narrow, elongated design and reduced reliance on reference layer modifications make it ideal for modern, high-density SerDes implementations.

Standard anti-pads 200 can define circular or oval voids in the reference plane, where the semicircular ends 204 of the anti-pad 201 are centered directly on each via 203 centers. In such configurations the only modifiable parameter is the radius 803 or width w1, w2 of the anti-pad, while the offset distance ‘b’ remains zero. This means the via 202 sits symmetrically within the anti-pad 201, and tuning impedance relies purely on expanding or narrowing the anti-pad width w1, w2 around the via 202.

In contrast, the narrow anti-pad 300 geometry of the instant disclosure introduces a narrow, elongated anti-pad, where each semicircular end 204 is offset 802 from its respective via center 203 by a finite distance, thereby introducing a nonzero offset dimension ‘b’. The semicircular end 204 center are now located outside of the via centers 203, causing the anti-pad to extend longitudinally while maintaining a much narrower width. This approach significantly changes the way return currents are distributed around the via 202, leading to improved impedance control and minimized electromagnetic disturbance in high-frequency environments. Structurally, in some aspects, the narrow anti-pad 300 geometry can be visualized as a capsule-shaped opening (i.e., elongated in the direction of signal propagation) where the central region is substantially narrow, and the semicircular ends 204 are shifted outward from the via centers 203. By increasing the length 13 of the anti-pad 201 without proportionally increasing its width w3, the narrow anti-pad 300 can maintain a compact lateral footprint that is useful for tight-pitch BGA environments, while still achieving a desirable impedance profile. The extended length 13 can help accommodate the fringe fields of high-speed differential signals more effectively, thus reducing reflections and discontinuities in the signal path.

In some aspects, the narrow anti-pad 300 can minimize cutouts in the reference planes, since it does not require as much space laterally as standard anti-pad 200 designs. This can preserve more of the continuous ground or power plane beneath the vias 202, which in turn can enhance signal return paths and improve power integrity. The narrowed profile can also facilitate better isolation between neighboring via 202 pairs and reduces the chance of interference, making the geometry highly scalable for dense multi-lane SerDes applications.

### Embodiments

One embodiment of the narrow anti-pad 300 can include a signal transition structure comprising, a via extending through a printed circuit board (PCB) substrate, the via defining a pitch and a via center, an anti-pad disposed about the via, the anti-pad comprising a geometry defining a length, a width, and a semicircular end and a displacement distance between the semicircular end and the via center. In some embodiments, the signal transition structure can include wherein the semicircular end and the via center are not coaxial. In some embodiments, the signal transition structure can include wherein the semicircular end is displaced from the via center so that the length is greater than the width. In some embodiments, the signal transition structure can include wherein the anti-pad geometry defines a substantially narrow cross-section.

In some embodiments, the signal transition structure can include wherein the cross-section is substantially ovular. In some embodiments, the signal transition structure can include wherein the length extends in a direction of signal routing. In some embodiments, the signal transition structure can include wherein the structure is configured for use with an ASIC flip-chip package. In some embodiments, the signal transition structure can include wherein the length is greater than the via pitch. In some embodiments, the signal transition structure can include wherein the anti-pad is oriented to align with a power flow of an underlying power plane of the PCB. In some embodiments, the signal transition structure can include wherein the via is part of a high speed SerDes interface.

Another embodiment of the narrow anti-pad 300 can include a printed circuit board (PCB) structure for routing high-speed differential SerDes signals, comprising a plurality of vias arranged to define a differential pair defining a via pitch and a via center, a differential anti-pad surrounding each via of the plurality of vias of the differential pair, each anti-pad comprising a geometry defining a length, a width, a semicircular end and a displacement distance between the semicircular end and the via center. In some embodiments, the PCB structure can include wherein the semicircular end and the via center are not coaxial. In some embodiments, the PCB structure can include wherein the semicircular end is displaced from the via center so that the length is greater than the width. In some embodiments, the PCB structure can include wherein the anti-pad geometry defines a substantially narrow cross-section.

In some embodiments, the PCB structure can include wherein the cross-section is substantially ovular. In some embodiments, the PCB structure can include wherein the length extends in a direction of signal routing. In some embodiments, the PCB structure can include wherein the structure is configured for use with an ASIC flip-chip package. In some embodiments, the PCB structure can include wherein the length is greater than the via pitch. In some embodiments, the PCB structure can include wherein the anti-pad is oriented to align with a power flow of an underlying power plane of the PCB. In some embodiments, the PCB structure can include wherein the via is part of a high speed SerDes interface.

In some embodiments, the structure can include wherein the elongated geometry comprises opposed semicircular ends each offset from the via center by the displacement distance. In some embodiments, the structure can include wherein the elongated geometry defines an ovular cross-sectional shape. In some embodiments, the structure can include wherein the elongated geometry defines a capsule-shaped cross-section. In some embodiments, the structure can include wherein the length is oriented substantially parallel to a signal routing direction. In some embodiments, the structure can include wherein the via is configured to electrically couple differential serializer/deserializer (SerDes) signals. In some embodiments, the structure can include wherein the via is part of an application-specific integrated circuit (ASIC) flip-chip package interface. In some embodiments, the structure can include wherein the length exceeds the via pitch. In some embodiments, the structure can include wherein the anti-pad is aligned with a direction of power flow in an underlying power plane of the PCB substrate.

In some embodiments, the structure can include wherein the elongated geometry reduces parasitic capacitance compared to a standard anti-pad geometry having concentric semicircular ends. In some embodiments, the structure can include wherein comprising a pair of vias configured as a differential pair, wherein each via of the pair includes a respective anti-pad with an elongated geometry. In some embodiments, the structure can include wherein each respective anti-pad geometry is configured to minimize crosstalk between the vias of the differential pair. In some embodiments, the structure can include wherein the displacement distance and the width are independently tunable to achieve a predetermined differential impedance. In some embodiments, the structure can include wherein the via defines a conductive path electrically coupling multiple layers of the PCB substrate. In some embodiments, the structure can include wherein the anti-pad is structured to preserve continuity of an adjacent reference plane of the PCB substrate. In some embodiments, the structure can include wherein the width of the elongated geometry is configured to minimize disruption of current flow in an underlying power plane. In some embodiments, the structure can include wherein the elongated geometry is further configured to reduce electromagnetic interference (EMI) by maintaining continuous reference plane integrity adjacent to the via.

In some embodiments, the structure can include wherein each elongated geometry is symmetrical about a central axis extending through respective via centers of the differential pair. In some embodiments, the structure can include wherein the elongated geometry comprises a rounded rectangular cross-section. In some embodiments, the structure can include wherein the elongated geometry is configured to provide a smooth impedance transition from the via to adjacent conductive traces.

### CONCLUSION

As used herein, including in the claims, the phrases “at least one of” or “one or more of” a list of items refer to any combination of those items, including single members. For example, “at least one of: A, B, or C” covers the possibilities of: A only, B only, C only, a combination of A and B, a combination of A and C, a combination of B and C, and a combination of A, B, and C. Additionally, the terms “comprise,” “comprises,” “comprising,” “include,” “includes,” and “including” are intended to be non-limiting and open-ended. These terms specify essential elements or steps but do not exclude additional elements or steps, even when a claim or series of claims includes more than one of these terms.

While the present disclosure has been detailed and depicted through specific embodiments and examples, it is to be understood by those skilled in the art that numerous variations and modifications can perform equivalent functions or yield comparable results. Such alternative embodiments and variations, which may not be explicitly mentioned but achieve the objectives and adhere to the principles disclosed herein, fall within its spirit and scope. Accordingly, they are envisioned and encompassed by this disclosure, warranting protection under the claims associated herewith. That is, the present disclosure anticipates combinations and permutations of the described elements, operations, steps, methods, processes, algorithms, functions, techniques, modules, circuits, etc., in any manner conceivable, whether collectively, in subsets, or individually, further broadening the ambit of potential embodiments.

Although operations, steps, instructions, and the like are shown in the drawings in a particular order, this does not imply that they must be performed in that specific sequence or that all depicted operations are necessary to achieve desirable results. The drawings may schematically represent example processes as flowcharts or flow diagrams, but additional operations not depicted can be incorporated. For instance, extra operations can occur before, after, simultaneously with, or between any of the illustrated steps. In some cases, multitasking and parallel processing might be beneficial. Furthermore, the separation of system components described should not be interpreted as mandatory for all implementations, as the program components and systems can be integrated into a single software product or distributed across multiple software products.

As used throughout, the singular forms “a,” “an,” and “the” include plural referents unless the context clearly dictates otherwise. Thus, for example, reference to a quantity of one of a particular element can comprise two or more such elements unless the context indicates otherwise. In addition, any of the elements described herein can be a first such element, a second such element, and so forth (e.g., a first widget and a second widget, even if only a “widget” is referenced).

Ranges can be expressed herein as from “about” one particular value and/or to “about” another particular value. When such a range is expressed, another aspect comprises from the one particular value and/or to the other particular value. Similarly, when values are expressed as approximations, by use of the antecedent “about” or “substantially,” it will be understood that the particular value forms another aspect. It will be further understood that the endpoints of each of the ranges are significant both in relation to the other endpoint and independently of the other endpoint.

For purposes of the current disclosure, a material property or dimension measuring about X or substantially X on a particular measurement scale measures within a range between X plus an industry-standard upper tolerance for the specified measurement and X minus an industry-standard lower tolerance for the specified measurement. Because tolerances can vary between different materials, processes, and between different models, the tolerance for a particular measurement of a particular component can fall within a range of tolerances.

As used herein, the terms “optional” or “optionally” mean that the subsequently described event or circumstance may or may not occur, and that the description comprises instances where said event or circumstance occurs and instances where it does not.

What is claimed is:

1. A signal transition structure comprising:
a via extending through a printed circuit board (PCB) substrate, the via defining a via pitch and a via center; and
an anti-pad disposed about the via, the anti-pad comprising an elongated geometry defining a length, a width narrower than the length, and at least one semicircular end, wherein a center of the semicircular end is offset from the via center by a displacement distance greater than zero, the elongated geometry configured such that the length is a sum of the via pitch and two times the sum of a radius of the semicircular end and the displacement distance.

2. The signal transition structure of claim 1, wherein the elongated geometry comprises opposed semicircular ends each offset from the via center by the displacement distance.

3. The signal transition structure of claim 1, wherein the elongated geometry defines an ovular cross-sectional shape.

4. The signal transition structure of claim 1, wherein the elongated geometry defines a capsule-shaped cross-section.

5. The signal transition structure of claim 1, wherein the length is oriented substantially parallel to a signal routing direction.

6. The signal transition structure of claim 1, wherein the via is configured to electrically couple differential serializer/deserializer (SerDes) signals.

7. The signal transition structure of claim 1, wherein the via is part of an application-specific integrated circuit (ASIC) flip-chip package interface.

8. The signal transition structure of claim 1, wherein the length exceeds the via pitch.

9. The signal transition structure of claim 1, wherein the anti-pad is aligned with a direction of power flow in an underlying power plane of the PCB substrate.

10. The signal transition structure of claim 1, wherein the elongated geometry reduces parasitic capacitance compared to a standard anti-pad geometry having concentric semicircular ends.

11. The signal transition structure of claim 1, further comprising a pair of vias configured as a differential pair, wherein each via of the pair includes a respective anti-pad with an elongated geometry.

12. The signal transition structure of claim 11, wherein each respective anti-pad geometry is configured to minimize crosstalk between the vias of the differential pair.

13. The signal transition structure of claim 1, wherein the displacement distance and the width are independently tunable to achieve a predetermined differential impedance.

14. The signal transition structure of claim 1, wherein the via defines a conductive path electrically coupling multiple layers of the PCB substrate.

15. The signal transition structure of claim 1, wherein the anti-pad is structured to preserve continuity of an adjacent reference plane of the PCB substrate.

16. The signal transition structure of claim 1, wherein the width of the elongated geometry is configured to minimize disruption of current flow in an underlying power plane.

17. The signal transition structure of claim 1, wherein the elongated geometry is further configured to reduce electromagnetic interference (EMI) by maintaining continuous reference plane integrity adjacent to the via.

18. The signal transition structure of claim 1, wherein the elongated geometry comprises a rounded rectangular cross-section.

19. The signal transition structure of claim 1, wherein the elongated geometry is configured to provide a smooth impedance transition from the via to adjacent conductive traces.

20. A printed circuit board (PCB) comprising:
a substrate having a plurality of conductive layers including at least one reference plane layer;
at least one via extending through the substrate and electrically coupling at least two of the plurality of conductive layers, the via defining a via center; and
an anti-pad formed in the at least one reference plane layer, the anti-pad having a narrow, elongated geometry defining a length and a width narrower than the length, the anti-pad including at least one semicircular end having a center offset from the via center by a displacement distance greater than zero, wherein the anti-pad length equals a via pitch associated with the via plus two times the sum of a radius of the semicircular end and the displacement distance.
